(19) United States
(12) Patent Application Publication
(10) Pub. No.: US 2012/0200288 A1
(43) Pub. Date: Aug. 9, 2012

(54) Apparatus for Measuring Hall Effect

(76) Inventors: Suk Whan Jung, Gyeonggi-do (KR); Geun Taek Lee, Seoul (KR); Young Kyu Park, Gyeonggi-do (KR); Ahn Su Lee, Gyeonggi-do (KR)

(21) Appl. No.: 13/128,899

(22) PCT Filed: Nov. 11, 2009
(86) PCT No.: PCT/KR09/06616

§ 371 Date: Jul. 12, 2011

(30) Foreign Application Priority Data
Nov. 12, 2008 (KR) 10-2008-0112090

(51) Int. Cl. G01R 33/07

(52) U.S. Cl. 324/235

(57) ABSTRACT

The present invention relates to a hall-effect measuring apparatus for measuring characteristic values of a semiconductor using hall-effect. In an embodiment of the present invention, the hall-effect measuring apparatus for measuring characteristic values of a semiconductor sample using hall-effect comprises a magnetic flux density applying device for accommodating a sample holder where the sample is set therein and moving permanent magnets by an electric motor installed at one side thereof to form a certain magnetic field at the sample; and a sample temperature control means for setting temperature of the sample by controlling temperature of the sample holder, in which current is applied to the sample, and hall voltage outputted from the sample is measured.

### TECHNICAL FIELD

The present invention relates to a hall-effect measuring apparatus, and more specifically to a hall-effect measuring apparatus, which is convenient to use since a process of applying magnetic flux density to a sample is automatically performed using permanent magnets and capable of easily grasping hall voltage with respect to changes of polarity while varying temperature conditions.

### BACKGROUND ART

Generally, a hall device is a kind of device for measuring and detecting or calculating magnetic flux or current using hall-effect, which is fabricated in a shape of a thin plate using a compound of germanium, indium and antimony (InSb), a compound of gallium and arsenide (GaAs), or the like having a large hall constant and a small temperature coefficient.

In addition, the hall-effect of the hall device is a phenomenon of flowing current by an electric potential difference (hall voltage) generated in a direction perpendicular to the current and magnetic field when the hall device is placed in the magnetic field having a component perpendicular to the direction of the current flowing through a conductor or a semiconductor, and the hall voltage is generated when density of carrier (electron or hole) in the conductor (or semiconductor) is shifted by the magnetic field.

A hall-effect measuring apparatus is a kind of equipment for accurately grasping mobility, concentration, hall coefficient, resistivity, conductivity, and the like of the carrier, which are electrical characteristics of a semiconductor device as well as a display device. The hall-effect measuring apparatus is essentially provided in a semiconductor-related laboratory or a semiconductor factory, and necessity of the hall-effect measuring apparatus tends to grow further more recently as studies on semiconductor devices of a new material having high luminance and high output power are actively carried out.

As an example of the hall-effect measuring apparatus, there is “apparatus and method for measuring hall-effect” of Korean Patent Reg. No. 10-0419005.

However, the hall-effect measuring apparatus has a problem in that measuring processes are not automatically connected since permanent magnets for forming a certain magnetic field at a sample are moved manually, and values of hall-effect measurement cannot be obtained under various temperature conditions since only temperature condition of liquid nitrogen is provided.

### DISCLOSURE OF INVENTION

### Technical Problem

Therefore, the present invention has been made in view of the above problems, and it is an object of the present invention to provide a hall-effect measuring apparatus for measuring characteristic values of a semiconductor sample using hall-effect, comprising a magnetic flux density applying device for accommodating a sample holder where the sample is set therein and moving permanent magnets by an electric motor installed at one side thereof to form a certain magnetic field at the sample; and a sample temperature control means for setting temperature of the sample by controlling temperature of the sample holder, in which current is applied to the sample, and hall voltage outputted from the sample is measured.

### Technical Solution

To accomplish the above object, according to one aspect of the present invention, there is provided a hall-effect measuring apparatus for measuring characteristic values of a semiconductor sample using hall-effect, the apparatus comprising: a magnetic flux density applying device for accommodating a sample holder where the sample is set therein and moving permanent magnets by an electric motor installed at one side thereof to form a certain magnetic field at the sample; and a sample temperature control means for setting temperature of the sample by controlling temperature of the sample holder, in which current is applied to the sample, and hall voltage outputted from the sample is measured.

According to a preferred embodiment of the present invention, the magnetic flux density applying device includes: a case having a hollow space therein and forming an opening at one side; a cover combined with the sample holder where the sample is set and covering the opening; a sample storage box installed inside the case to store the sample holder; permanent magnets mounted at both ends of a moving member described below in pairs, in which magnet surfaces having opposite polarities face each other so as to form the predetermined magnetic field at the sample stored in the sample storage box; and the moving member for moving the permanent magnets to a position for forming the magnetic field at the sample.

According to a preferred embodiment of the present invention, the electric motor having a rotating gear is installed at one side of the case, and a timing belt or a rack gear engaged with the rotating gear is provided at one side of the moving member, and thus the moving member moves along a guide rail installed in a direction of length inside the case by operation of the electric motor.

According to a preferred embodiment of the present invention, liquid nitrogen or a cooling gas is provided in the sample storage box, and moisture generated at the sample when a low temperature is applied is prevented by continuous evaporation of the liquid nitrogen or continuous supply of the cooling gas.

According to a preferred embodiment of the present invention, the sample temperature control means includes: a liquid nitrogen container provided on a top of the magnetic flux density applying device to store the liquid nitrogen for cooling down the sample; and a heater installed at one side of the sample holder, in which temperature of the sample is set by applying current to the heater.

According to a preferred embodiment of the present invention, the liquid nitrogen container includes: a main body for storing the liquid nitrogen; and a heat transfer unit, one end of which is connected to a bottom surface of the main body, and the other end is formed to be extended into the magnetic flux density applying device.

According to a preferred embodiment of the present invention, the heat transfer unit includes: a coupling unit combined on a bottom surface of the main body and having a cross-sectional area of a circular shape; a supporting unit formed to be extended toward outside from the coupling unit and forming a rod heater insertion having of a certain depth in a radial direction; and a protrusion unit formed to be extended into the magnetic flux density applying device from the supporting unit and having a cross-sectional area of a rectangular shape, in which the sample holder is mounted on the protrusion unit.

### Advantageous Effects

The hall-effect measuring apparatus according to an embodiment of the present invention is advantageous in that hall-effect can be further precisely confirmed by continuously grasping hall voltage with respect to changes of polarity while varying temperature of a sample, which is a target to be measured, and since magnetic flux density can be automatically applied, the hall-effect measuring apparatus is convenient to use, and the time required for measuring the hall-effect can be reduced.

### BRIEF DESCRIPTION OF THE DRAWINGS

FIG. 1 is a perspective view showing the configuration of a hall-effect measuring apparatus according to an embodiment of the present invention.

FIG. 2 is a perspective view showing a magnetic flux density applying device using permanent magnets according to an embodiment of the present invention.

FIG. 3 is an exploded perspective view of FIG. 2.

FIG. 4 is a perspective view showing a sample holder according to an embodiment of the present invention.

FIG. 5 is a cross-sectional side view showing a liquid nitrogen container according to an embodiment of the present invention.

FIGS. 6 and 7 are views showing using states of a magnetic flux density applying device using permanent magnets according to an embodiment of the present invention.

FIG. 8 is a block diagram showing a hall voltage measuring means applied to a hall-effect measuring apparatus according to an embodiment of the present invention.

FIG. 9 is an overall flowchart illustrating the steps of measuring hall voltage according to an embodiment of the present invention.

FIG. 10 is a flowchart illustrating a process of measuring hall-effect shown in FIG. 9.

FIG. 11 is a flowchart illustrating a process of measuring I-V and I-R shown in FIG. 9.

FIG. 12 is a flowchart illustrating a process of measuring temperature characteristics shown in FIG. 9.

FIG. 13 is a view showing a hall-effect measurement screen displayed according to an embodiment of the present invention.

FIG. 14 is a view showing an I-V I-R measurement screen displayed according to an embodiment of the present invention.

FIG. 15 is a view showing a temperature characteristic measurement screen displayed according to an embodiment of the present invention.

### BEST MODE FOR CARRYING OUT THE INVENTION

The preferred embodiments of the present invention will be hereafter described in detail, with reference to the accompanying drawings. Furthermore, in the drawings illustrating the embodiments of the present invention, elements having like functions will be denoted by like reference numerals and details thereon will not be repeated.

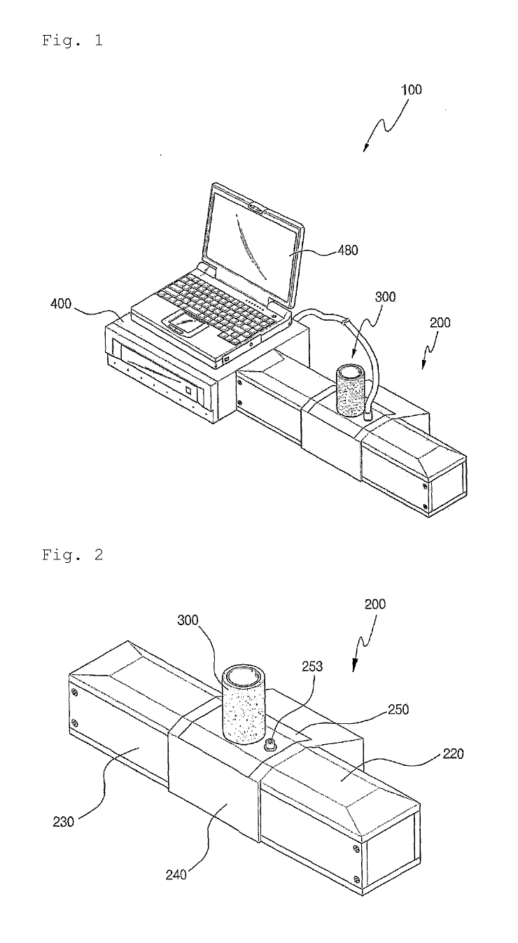

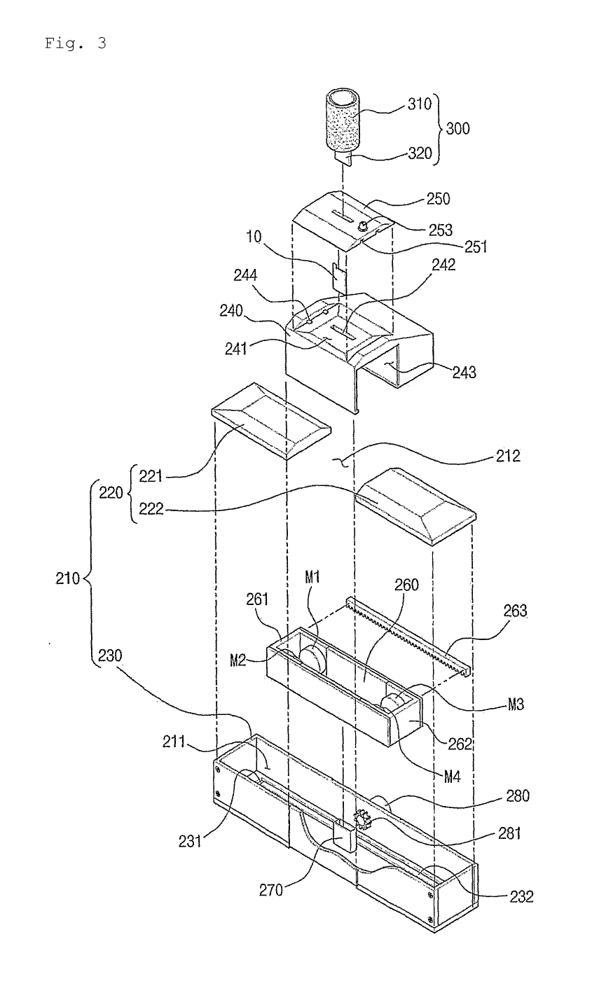

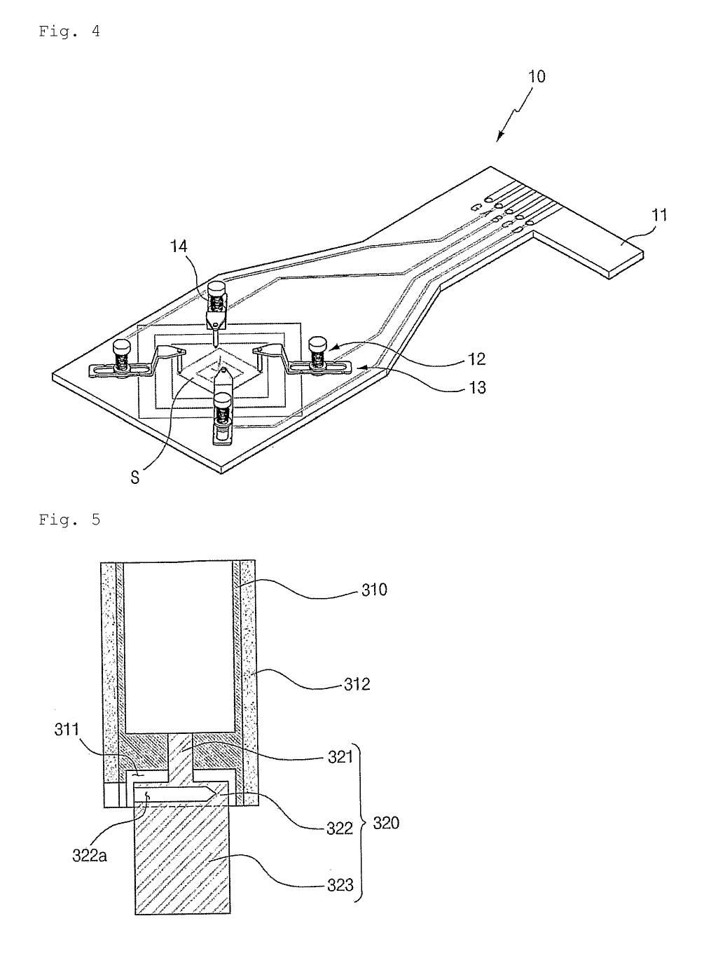

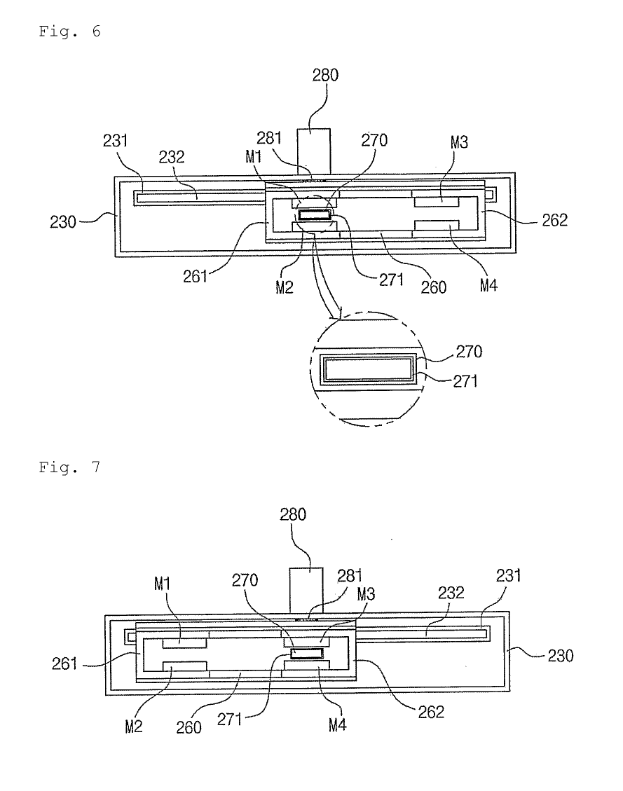

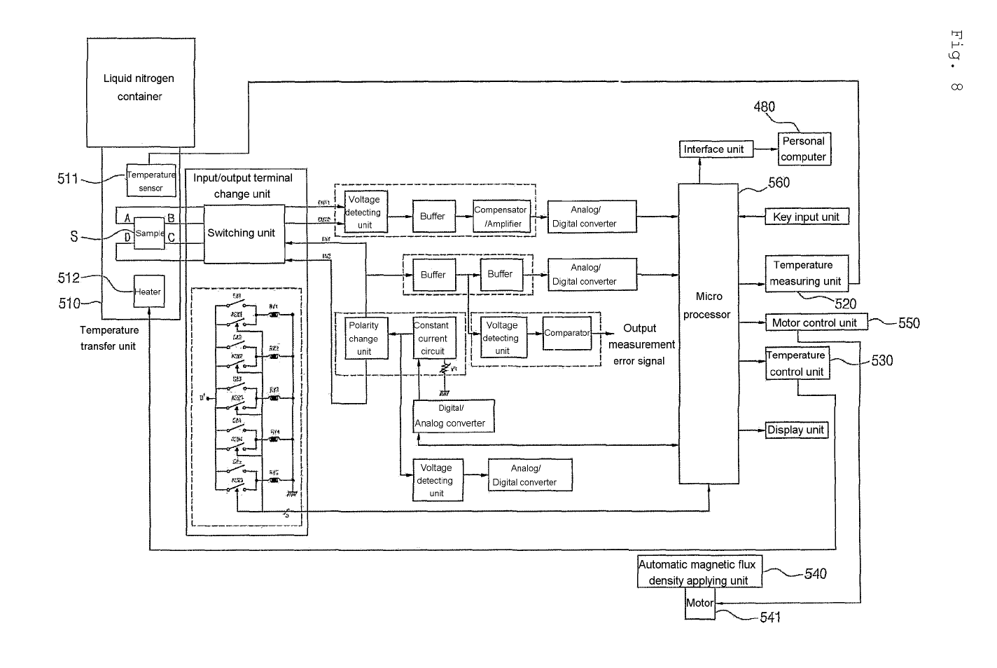

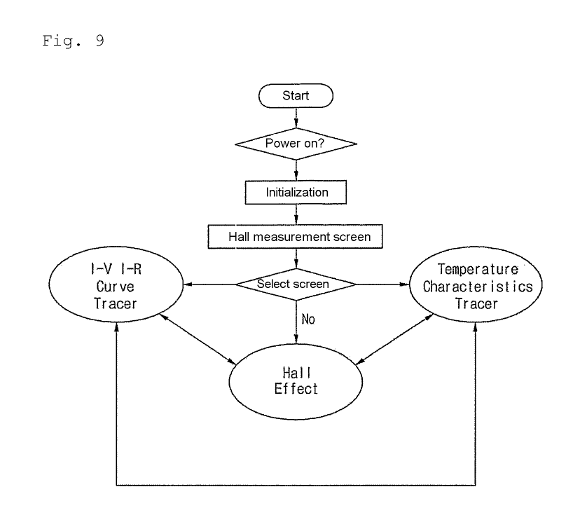

FIG. 1 is a perspective view showing the configuration of a hall-effect measuring apparatus according to an embodiment of the present invention, FIG. 2 is a perspective view showing a magnetic flux density applying device using permanent magnets according to an embodiment of the present invention, FIG. 3 is an exploded perspective view of FIG. 2, FIG. 4 is a perspective view showing a sample holder according to an embodiment of the present invention, FIG. 5 is a cross-sectional side view showing a liquid nitrogen container according to an embodiment of the present invention, and FIGS. 6 and 7 are views showing using states of a magnetic flux density applying device using permanent magnets according to an embodiment of the present invention.

As shown in FIG. 1, the hall-effect measuring apparatus 100 according to an embodiment of the present invention comprises a magnetic flux density applying device 200 for forming a magnetic field at a sample (not shown), and a sample temperature control means for controlling temperature of a sample holder 10 to set temperature of the sample on which the measurement is performed. Current is applied to the sample holder 10 where the sample is set, and output values such as hall voltage and the like outputted from the sample are measured. Then, a variety of characteristic values related to the sample, such as a hall coefficient, hall mobility and the like, are calculated and displayed.

Here, as shown in FIGS. 2 and 3, the magnetic flux density applying device 200 includes a case 210 having a hollow space 211 therein and forming an opening 212 at one side, a cover 250 combined with the sample holder 10, where the sample is set, at one side and covering the opening 212, a sample storage box 270 installed inside the case 210 to store the sample holder, permanent magnets M1 to M4 for forming a certain magnetic field at the sample, and a moving member 260 for moving the permanent magnets in order to form the magnetic field at the sample.

The case 210 can be divided into an upper case 220 and a lower case 230. The lower case 230 is a cabinet-type whose top is open, and the upper case 220 is combined on the top of the lower case 230.

At this point, a first upper case 221 and a second upper case 222 of the upper case 220 are combined at both ends of the top of the lower case 230 to be apart from each other, and a cover rest 240 is combined at the opening 212 formed between the first and second upper cases 221 and 222.

The cover rest 240 is for supporting the cover 250 described below, in which a rest groove 241 is formed on the top surface to be combined with the cover 250, and a rectangular cutout hole 242 is formed at the center of the rest groove 241 to expose the top surface of the sample storage box 270 described below.

In addition, the front surface of the cover rest 240 is bent downward from the front end of the top surface to cover the central portion of the front surface of the lower case 230, and the rear surface of the cover rest 240 is bent downward from the rear end of the top surface to cover the central portion of the rear surface of the lower case 230. The cover rest 240 is bent downward from the rear end of the top surface, slightly slanting toward outside to have a hollow space 243, to accommodate an electric motor 280 described below.

The cover 250 is detachably combined with the rest groove 241 of the cover rest 240. At this point, fixing grooves 251 are formed at both ends of the bottom surface of the cover in order to prevent movement of the cover 250 while performing a measuring work, and fixing prominences 244 are preferably formed on the cover rest 240 to be correspondent to the fixing grooves. The fixing prominences 244 of the cover rest 240 are inserted into the fixing grooves 251 of the cover 250, and thus movement of the cover 250 is prevented.

A connection terminal (not shown) is provided at one side of the bottom surface of the cover 250, and the sample holder 10 where the sample is set is combined with the bottom surface of the cover 250. The sample holder 10 is preferably configured in a spring clip board (SPCB) form that is advantageous for 4-terminal contact, and the sample holder is accommodated inside the sample storage box 270 described below when the cover 250 is combined with the cover rest 240 so that the sample set in the sample holder 19 can be placed inside the sample storage box 270.

FIG. 4 shows an embodiment of the sample holder 10 of the SPCB form that is advantageous for 4-terminal contact, and the sample holder 10 includes a printed circuit board (PCB) 11, four guide pins 12 perpendicularly fixed to the PCB 11, and four clips 13, one end of each is combined with the guide pin 12, and the other end is elastically supported by a coil spring 14 at one side of the set sample S. Since the sample S is elastically supported by the coil springs 14, it is advantageous in that the sample S is easy to set and replace.

At this point, temperature of the sample holder 10 can be controlled by supplying power to a heater (not shown) provided at one side of the sample holder 10, and accordingly, the sample S set on the sample holder 10 can be set to a temperature value desired for performing the measurement.

In addition, the sample holder 10 can be utilized in a system that can be easily applied to a case where temperature changes at a high temperature (about 500K), as well as a case where temperature changes at a low to room temperatures. In this case, since non-uniformity of temperature at a high temperature can be improved by uniformly supplying heat capacity using the liquid nitrogen container 300 mounted at one side of the top of the cover 250, a precise temperature can be set, and it is preferable to substitute a high-temperature insulation case for the sample storage box 270 described below.

In addition, a connection terminal 253 electrically connected to a main body 400 of the measuring apparatus is provided at one side of the top of the cover 250, and the liquid nitrogen container 300 is mounted at one side of the connection terminal 253. The liquid nitrogen container 300 allows characteristics of the sample to be measured in an extremely low atmosphere (about 77K) by lowering internal temperature of the sample storage box 270 described below to an extremely low temperature.

That is, a sample temperature control means according to an embodiment of the present invention includes a heater installed inside the sample holder 10, and the liquid nitrogen container 300 mounted at one side of the top of the cover 250. After rapidly cooling down inside of the sample storage box 270 by an extremely low temperature of the liquid nitrogen contained in the liquid nitrogen container 300, the sample temperature control means supplies power to the heater to set temperature of the sample to a temperature at which characteristic values are measured. At this point, since the sample storage box 270 is filled with the liquid nitrogen, rapid cooling and uniformity of temperature are guaranteed. In addition, owing to rapid and uniform conduction of temperature and uniform distribution of temperature to the entire sample holder 10, characteristics of the sample with respect to changes of temperature can be effectively grasped.

In addition, the liquid nitrogen in the sample storage box 270 is maintained to a certain amount to allow continuous evaporation of nitrogen gas, and thus moisture generated at the sample when a low temperature is applied can be prevented. Therefore, a system capable of preventing generation of moisture when a low temperature is applied, which could not be implemented conventionally without using a vacuum chamber, has been implemented. At this point, it is possible to prevent generation of moisture when a low temperature is applied, by continuously supplying the cooling gas, such as nitrogen, hydrogen, helium, or the like, into the sample storage box 270.

Accordingly, since a complicated apparatus, such as a vacuum chamber, a pump, or the like, does not need to be installed as is done conventionally in order to prevent generation of moisture at the sample when a low temperature is applied, it is easy to install and maintain the hall-effect measuring apparatus, and cost of the hall-effect measuring apparatus can be reduced.

Here, the liquid nitrogen container 300 includes a cylinder-shaped main body 310 made of a synthetic resin material for storing the liquid nitrogen, and a metallic heat transfer unit 320, one end of which is connected to the bottom surface of the main body 310 and the other end is formed to be extended into the sample storage box 270. The heat transfer unit 320 is constructed using a metal such as brass having an excellent heat transfer rate and thus internal temperature of the sample storage box 270 is gradually lowered to an extremely low temperature. At this point, the heat transfer unit 320 is placed in line with the sample holder 10 contained in the sample storage box 270 to be apart from each other by a certain distance.

Here, as shown in FIG. 5, the heat transfer unit 320 includes a coupling unit 321 combined at the central portion of the bottom surface of the cylinder-shaped main body 310 to expose the top surface and having a cross-sectional area of a circular shape, a supporting unit 322 formed to be extended toward outside from the coupling unit 321 and having a cross-sectional area of a circular shape, and a protrusion unit 323 formed to be extended into the sample storage box 270 from the supporting unit 322 and having a cross-sectional area of a rectangular shape, the width of which is as long as the diameter of the supporting unit 322.

In addition, a depression unit 311 of a certain depth is formed on the bottom surface of the main body 310, and the supporting unit 322 is formed slightly apart from the bottom surface of the depression unit 311. A rod heater insertion hole 322a having a certain depth is preferably formed at one side of the supporting unit 322 in the radial direction, and the outer periphery of the main body 310 is preferably wrapped with a heat insulating material 312 to prevent heat loss.

At this point, a rod heater (not shown) is inserted into the rod heater insertion hole 322a, and the sample holder 10 of an SPCB form where the sample is set can be mounted on the protrusion unit 323.

That is, in the embodiment described above, a heater is installed at one side or inside of the sample holder 10, and thus temperature of the sample can be set. However, in another embodiment of the present invention, a rod heater (not shown) is installed in the rod heater insertion hole 322a of the supporting unit 322, and heat generated by the rod heater is transferred from the supporting unit 322 to the protrusion unit 323. Accordingly, temperature of the sample holder 10 mounted at one side of the protrusion unit 323 is controlled, and thus temperature of the sample set in the sample holder 10 can be set.

On the other hand, instead of mounting the liquid nitrogen container 300 on the top of the cover 250, it is possible to form a penetrating hole at the cover rest 240 and the sample holder 10 to be correspondent to the sample storage box 270, combine a funnel-shaped injector with the penetrating hole, and inject liquid nitrogen into the sample storage box 270. In this case, the sample holder 10 where the sample is set is submerged into the liquid nitrogen and rapidly arrives at an extremely low temperature.

A rail groove 231 of a certain depth is formed at the rear end of the internal bottom surface of the lower case 230 in the direction of length of the lower case 230, and a guide rail 232 is installed at the rail groove 231.

Then, the moving member 260 rests on the guide rail 232 and moves along the guide rail 232. The moving member 260 is a cabinet-type, both sides of which are open, and the sample storage box 270 wrapped with a heat insulating material 271 is installed on the central portion of the bottom surface of the moving member 260. Permanent magnet fixtures 261 and 262 having a cross-sectional area of a [symbol] shape are respectively combined at both sides of the moving member 260, in which a pair of permanent magnets M1 and M2, or M3 and M4 is mounted to be apart from and face each other in the direction of width.

At this point, a pair of permanent magnets M1 and M2, or M3 and M4 is mounted such that surfaces having opposite polarities face each other. If the N-pole is installed at the front end and the S-pole is installed at the rear end of the permanent magnet fixture 261 at one side of the moving member 260, the S-pole is installed at the front end and the N-pole is installed at the rear end of the permanent magnet fixture 262 at the other side of the moving member 260, and as shown in FIG. 5, it is preferable to change polarities of the sample (N-pole to S-pole, S-pole to N-pole) as the moving member 260 moves.

In addition, it is preferable that the moving member 260 moves automatically by the electric motor 280. For example, the electric motor 280 is installed at one side of the rear surface of the lower case 230 to protrude an end portion of the electric motor into the lower case 230, and a rotating gear 281 is installed at the end portion of the electric motor 280. A rack gear 263 is installed on the rear surface of the moving member 260 in the direction of length to be engaged with the rotating gear 281. The electric motor 280 rotates forward or backward depending on a previously inputted value, or a controller (not shown) or the like operates the electric motor 280, and thus the moving member 260 where the rack gear 263 is installed can move along the guide rail 232 by the rotation of the rotating gear 281.

At this point, it is preferable that movement of the moving member 260 is sensed and controlled by a pair of location detecting sensors (not shown) installed at one side of the lower case 230 to be apart from each other by a certain distance, and a timing belt (not shown) can be used instead of the rack gear 263.

According to an embodiment of the present invention, the hall-effect measuring apparatus 100 can operate as described below.

The cover 250 is detached from the cover rest 240, and the sample holder 10 where the sample is set is connected to the connection terminal provided on the bottom surface of the cover 250.

Next, the cover 250 is combined with the cover rest 240 so that the sample storage box 270 may accommodate the sample holder 10, and at this point, the fixing prominences 244 of the cover rest 240 are inserted into the fixing grooves 251 of the cover 250 to prevent movement of the cover 250 while a measuring work is performed.

The liquid nitrogen container 300 is mounted on the top of the cover 250 so that the heat transfer unit 320 is accommodated in the sample storage box 270 and placed in line with the sample holder 10. Then, internal temperature of the sample storage box 270 is lowered to an extremely low temperature by injecting liquid nitrogen into the main body 310. At this point, it is also possible to directly fill the sample storage box 270 with the liquid nitrogen.

Next, the moving member 260 is moved by the operation of the electric motor 280, and as shown in FIG. 6, a pair of permanent magnets M1 and M2 provided at one side of the moving member 260 with the intervention of the sample storage box 270 therebetween faces each other and forms a magnetic field at the sample. Then, as constant current of a certain level flows from the main body 400 of the measuring apparatus to the sample holder 10 and the sample, characteristic values of the sample such as hall voltage and the like are confirmed.

In addition, when a hall coefficient and the like are desired to be measured with respect to changes of polarity, the electric motor 280 operate to face another pair of permanent magnets M3 and M4 provided at the other side of the moving member 260 each other with the intervention of the sample storage box 270 therebetween as shown in FIG. 7, and thus a measuring work can be easily performed. Accordingly, it is unnecessary to manually change and set the position of permanent magnets and wait for an extended period of time to cool down the sample to a predetermined temperature as is done conventionally, and automation of the hall-effect measuring apparatus can be accomplished.

On the other hand, if temperature arrives at a set temperature after a desired temperature condition is applied to each step, hall-effect is automatically measured, and electrical characteristics of the sample are sequentially stored. For example, the hall-effect can be measured in five steps at intervals of 10° C. in a section between −180° C. and −140° C.

At this point, temperature of the sample maintains −193° C. by liquid nitrogen before the heater of the sample holder 10 starts to operate, and if power is supplied to the heater, temperature of the sample gradually increases, together with temperature of the sample holder 10. If the tempature reaches at −180° C., the electric motor 280 starts to operate and a magnetic filed is formed at the sample as describe above, and characteristic values of the sample, such as a hall voltage and the like, are measured and stored in a personal computer 480.

Thereafter, characteristic values are measured at temperatures of −170° C., −160° C., −150° C. and −140° C. at intervals of 10° C. and the stored characteristic values can be confirmed through the personal computer 480. Since temperatures can be set rapidly and varied while minimizing temperature deviation through evaporation of the liquid nitrogen and heating of the heater as described above, researchers can easily measure the hall-effect with respect to changes of desired temperature.

At this point, the worker can confirm desired calculation values, such as concentration, mobility, and the like, among the characteristic values measured and stored depending on each temperature condition, using a program provided in the personal computer 480. In addition, the worker can measure I-V and I-R by sequentially confirming four terminals of the contacted sample. Furthermore, the worker can measure I-V and I-R for only one terminal with respect to changes of temperature in order to simply and rapidly confirm the characteristic values.

Here, since a method of measuring hall-effect and a method of calculating characteristic values such as a hall coefficient, mobility, and the like using the hall-effect measuring method are described in detail in “apparatus and method for measuring hall-effect” of Korean Patent Reg. No. 10-0419005, which is a prior document of the invention, details thereof will be omitted, and a hall voltage measuring means of the present invention, which is the difference of the present invention from the previously registered patent, will be briefly described.

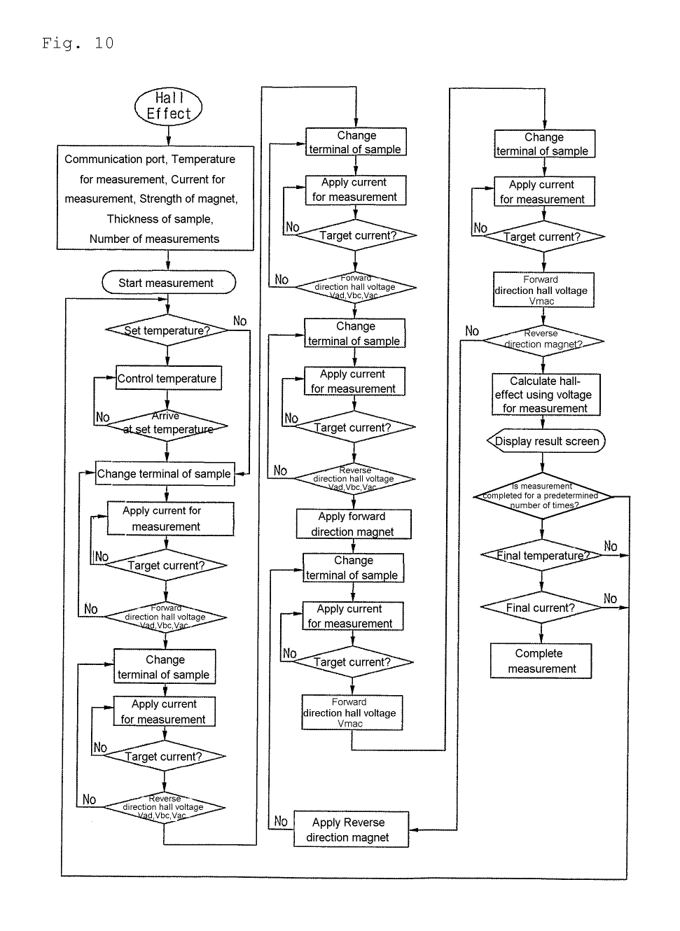

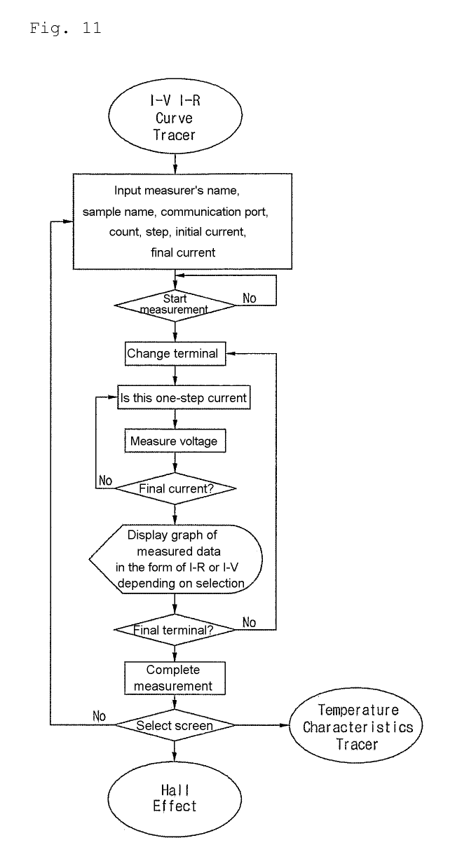

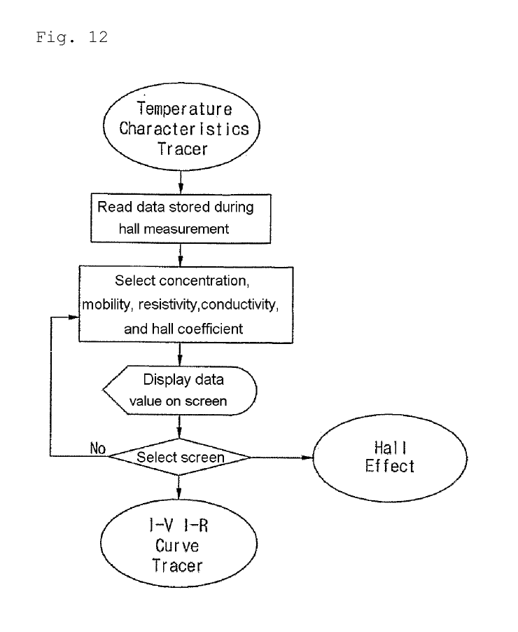

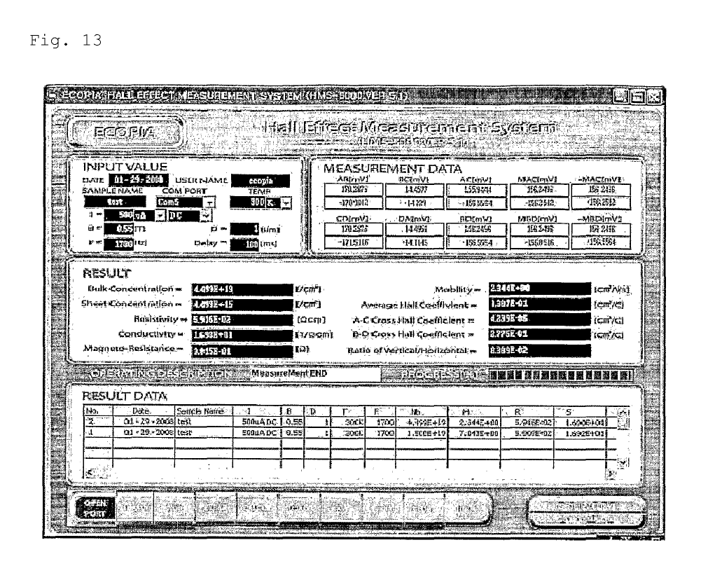

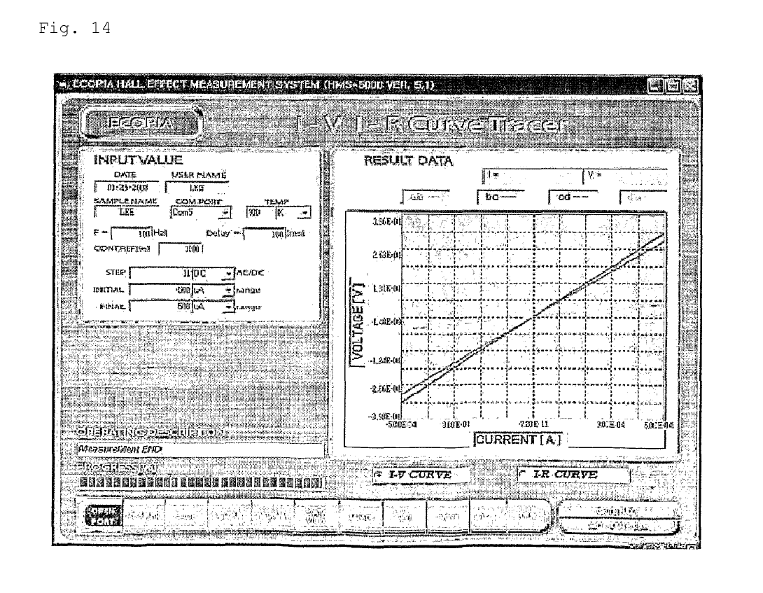

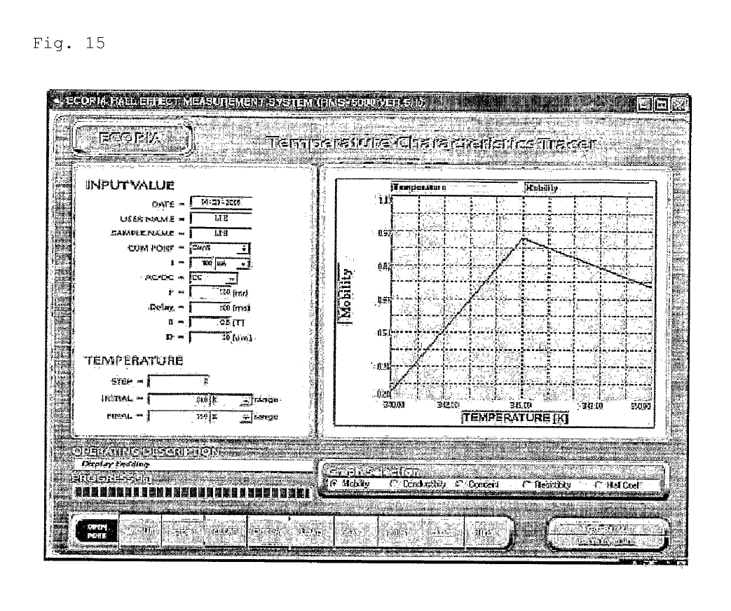

FIG. 8 is a block diagram showing a hall voltage measuring means applied to a hall-effect measuring apparatus according to an embodiment of the present invention, FIG. 9 is an overall flowchart illustrating the steps of measuring hall voltage according to an embodiment of the present invention, FIG. 10 is a flowchart illustrating a process of measuring hall-effect shown in FIG. 9, FIG. 11 is a flowchart illustrating a process of measuring I-V and I-R shown in FIG. 9, FIG. 12 is a flowchart illustrating a process of measuring temperature characteristics shown in FIG. 9, FIG. 13 is a view showing a hall-effect measurement screen displayed according to an embodiment of the present invention, FIG. 14 is a view showing an I-V I-R measurement screen displayed according to an embodiment of the present invention, and FIG. 15 is a view showing a temperature characteristic measurement screen displayed according to an embodiment of the present invention.

As shown in FIG. 8, the hall voltage measuring means according to an embodiment of the present invention is configured to be similar to the circuit diagram (refer to FIG. 13 of Korean Patent Reg. No. 10-0419005) publicized in the Korean Patent Reg. No. 10-0419005. However, it is different in that the hall voltage measuring means of the present invention further comprises a temperature transfer unit 510 on which a sample S is mounted, a temperature measuring unit 520 for measuring temperature of the sample S using a temperature sensor 511 installed at one side of the sample, a temperature control unit 530 for controlling operation of a heater 512 of the temperature transfer unit 510 depending on a temperature value measured by the temperature measuring unit 520, and a motor control unit 550 for controlling operation of a motor 541 installed at an automatic magnetic flux density applying unit 540.

At this point, the heater 512 shown in FIG. 8 is a rod heater installed in the rod heater insertion hole 322a of the supporting unit 322 shown in FIG. 5, and the sample holder 10 of an SPCB form, which contains a sample, has been already mounted on the protrusion unit 323.

The operation of the hall voltage measuring means according to an embodiment of the present invention configured as described above will be described with reference to FIGS. 9 to 15.

As shown in FIG. 9, if a worker turns on the power, a microprocessor 560 recognizes turn-on of the power and performs an initial operation, and a hall-effect measurement screen (refer to FIG. 13), i.e., a main screen, is displayed on the personal computer 480. Here, the worker may select an I-V and I-R measurement screen (refer to FIG. 14) or a temperature characteristics measurement screen (refer to FIG. 15).

Hall-effect is measured as shown in the flowchart of FIG. 10. The worker inputs a communication port, temperature for measurement, current for measurement, strength of magnet, thickness of sample, number of measurements, and the like through the hall-effect measurement screen shown in FIG. 13, and result values, such as concentration, mobility, resistivity, conductivity, hall coefficient, and the like, are displayed on the screen in real-time. At this point, applying a magnet in a forward or reverse direction is automatically performed by the motor control unit 550, and temperature of the sample is automatically set by the temperature control unit 530.

Before measuring the hall-effect, I-V and I-R can be measured as shown in the flowchart of FIG. 11 in order to confirm Ohmic contact of the sample.

At this point, the worker determines a value of the step, which is the number of measurements, after setting an initial value and a final value of the applied current depending on the electrical characteristics of the semiconductor sample. As the measurement starts, four characteristic graphs for I-V and I-R are automatically drawn as shown in FIG. 14 in a sequence, along four surfaces of the sample.

In addition, temperature characteristics are measured as shown in the flowchart of FIG. 12, and data values stored in the process of measuring the hall-effect are fetched, and a value selected among the values of concentration, mobility, resistivity, conductivity, and hall coefficient with respect to changes of temperature is displayed as shown in FIG. 15.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

### INDUSTRIAL APPLICABILITY

The hall-effect measuring apparatus according to an embodiment of the present invention is advantageous in that hall-effect can be further precisely confirmed by continuously grasping hall voltage with respect to changes of polarity while varying temperature of a sample, which is a target to be measured, and since magnetic flux density can be automatically applied, the hall-effect measuring apparatus is convenient to use, and the time required for measuring the hall-effect can be reduced.

1. A hall-effect measuring apparatus for measuring characteristic values of a semiconductor sample using hall-effect, the apparatus comprising:
a magnetic flux density applying device for accommodating a sample holder where the sample is set therein and moving permanent magnets by an electric motor installed at one side thereof to form a certain magnetic field at the sample; and
a sample temperature control means for setting temperature of the sample by controlling temperature of the sample holder, wherein current is applied to the sample, and hall voltage outputted from the sample is measured.

2. The apparatus according to claim 1, wherein the magnetic flux density applying device includes:
a case having a hollow space therein and forming an opening at one side;
a cover combined with the sample holder where the sample is set and covering the opening;
a sample storage box, installed inside the case to store the sample holder;
permanent magnets mounted at both ends of a moving member described below in pairs, in which magnet surfaces having opposite polarities face each other so as to form the predetermined magnetic field at the sample stored in the sample storage box; and
the moving member for moving the permanent magnets to a position for forming the magnetic field at the sample.

3. The apparatus according to claim 2, wherein the electric motor having a rotating gear is installed at one side of the case, and a timing belt or a rack gear engaged with the rotating gear is provided at one side of the moving member, and thus the moving member moves along a guide rail installed in a direction of length inside the case by operation of the electric motor.

4. The apparatus according to claim 2, wherein liquid nitrogen or a cooling gas is provided in the sample storage box, and moisture generated at the sample when a low temperature is applied is prevented by continuous evaporation of the liquid nitrogen or continuous supply of the cooling gas.

5. The apparatus according to claim 1, wherein the sample temperature control means includes:
a liquid nitrogen container provided on a top of the magnetic flux density applying device to store liquid nitrogen for cooling down the sample; and
a heater installed at one side of the sample holder, wherein temperature of the sample is set by applying current to the heater.

6. The apparatus according to claim 5, wherein the liquid nitrogen container includes:
a main body for storing the liquid nitrogen; and
a heat transfer unit, one end of which is connected to a bottom surface of the main body, and the other end is formed to be extended into the magnetic flux density applying device.

7. The apparatus according to claim 6, wherein the heat transfer unit includes:
a coupling unit combined on a bottom surface of the main body and having a cross-sectional area of a circular shape;
a supporting unit formed to be extended toward outside from the coupling unit and forming a rod heater insertion hole having a certain depth in a radial direction; and
a protrusion unit formed to be extended into the magnetic flux density applying device from the supporting unit and having a cross-sectional area of a rectangular shape, wherein the sample holder is mounted on the protrusion unit.

8. The apparatus according to claim 3, wherein liquid nitrogen or a cooling gas is provided in the sample storage box, and moisture generated at the sample when a low temperature is applied is prevented by continuous evaporation of the liquid nitrogen or continuous supply of the cooling gas.
